(19) United States
(12) Patent Application Publication
(10) Pub. No.: US 2013/0099825 A1
(43) Pub. Date: Apr. 25, 2013

(54) VOLTAGE COMPARATOR

(71) Applicant: Liang Cheng, Wuxi (CN)

(72) Inventor: Liang Cheng, Wuxi (CN)

(21) Appl. No.: 13/807,311

(22) PCT Filed: Nov. 25, 2011
(86) PCT No.: PCT/CN2011/082934

§ 371 Date: Dec. 28, 2012

(30) Foreign Application Priority Data
Dec. 22, 2010 (CN) 201010601379.3

(51) Int. Cl. H03K 5/24

(52) U.S. Cl. CPC H03K 5/2472
USPC 327/65

(57) ABSTRACT

The present disclosure provides a voltage comparator including a current source, a differential gain module and a switch module, wherein the magnitude of the current flowing through the current source is nano ampere level; the differential gain module includes a first transistor, a second transistor, a third transistor and a fourth transistor, wherein the first transistor and the second transistor are respectively connected to the current source, the third transistor and the fourth transistor form a mirror current structure, the third transistor is connected to the first transistor, and the fourth transistor is connected to the second transistor via a ninth transistor used for forming asymmetric differential gain.

### BACKGROUND

1. Technical Field

The present disclosure relates to image sensor, and particularly, to a voltage comparator.

2. Description of the Related Art

By the development of VLSI technology, CMOS image sensors can be integrated in a single chip with functions of analog/digital conversion, signal processing, automatic gain control, precise amplifying and data storing. The high integration greatly decreases the system complexity and cost. CMOS image sensors have extraordinary advantages of low power consumption, single power supply, low operating voltage (3V-5V), high yield and random accessing to partial image element. As a result, CMOS image sensors are developed to be utilized in various fields, such as consumer digital products, X-rays detection, astro observation and medical inspection, etc.

Voltage comparators are considered as critical circuits in the CMOS image sensors, the performance of the voltage comparators on latency time, power consumption, switching speed determines the performance of the whole CMOS image sensors. Therefore, high performance CMOS image sensors require the voltage comparator to have the above advantages, such as short latency time, low power consumption and occupating small area.

FIG. 1 is a schematic of a conventional partial positive feedback OTA voltage comparator. The voltage comparator includes a positive feedback module, an input differential module, a switch module, a current source. The positive feedback module includes two transistors M₉ and M₁₀ which are on active loads. The input differential module includes symmetric transistors M₁˜M₂. The switch module includes symmetric transistors M₅˜M₈.

In the voltage comparator, an effective transconductance Gₘ of the OTA can be increased by the partial positive feedback module according to formula (1); DC gain, frequency and bandwidth of unit gain can be increased via partial positive feedback according to formula (2), resulting in increasing the effective transconductance of the input gain stage.

$$\begin{matrix}{G}_{m} = \frac{\frac{{I}_{b}}{( 2 {nU}_{T} )}}{1 - \frac{{W}_{9}}{{W}_{3}}} & ( 1 ) \\ GBW = \frac{1}{1 - \frac{{W}_{9}}{{W}_{3}}} \frac{{I}_{b}}{4 π {nU}_{T} {C}_{L}} & ( 2 )\end{matrix}$$

wherein I_{b} is the bias current of the current source, U_{T}=kT/q=0.026V (if T=300 K), n is the weak reverse slope factor, W₃ and W₉ are respectively the channel width of transistor M₃ and transistor M₉, C_{L} is the load capacitance.

However, the topological structure of the voltage comparator as shown in FIG. 1 could provide good performance on anti-noise, but the voltage comparator has long latency time and may cause large deviation. Besides, the consumption of the voltage comparator is rather large. The latency time would become even longer if the power consumption of the voltage comparator could be managed to be lowered.

### SUMMARY

A voltage comparator includes: a current source; a switch module; and a differential gain module including a first transistor, a second transistor, a third transistor and a fourth transistor, wherein the first transistor and the second transistor are respectively connected to the current source, the third transistor and the fourth transistor cooperatively form a mirror current structure, the third transistor is connected to the first transistor, and the fourth transistor is connected to the second transistor via a ninth transistor used for forming asymmetric differential gain.

### BRIEF DESCRIPTION OF THE DRAWINGS

FIG. 1 is a schematic of a conventional partial positive feedback OTA voltage comparator.

FIG. 2 is a topological structure chart of voltage comparator in accordance with an exemplary embodiment of the present disclosure.

FIG. 3 is the output voltage transient response waveform of the voltage comparator in accordance with the present disclosure.

FIG. 4 shows the delay of waveform of the back edge of the output voltage relative to that of the input voltage respectively taken from the voltage comparator of the present embodiment and the conventional voltage comparator.

FIG. 5 shows the overall current waveforms in working state of the voltage comparator of the present embodiment and the conventional voltage comparator.

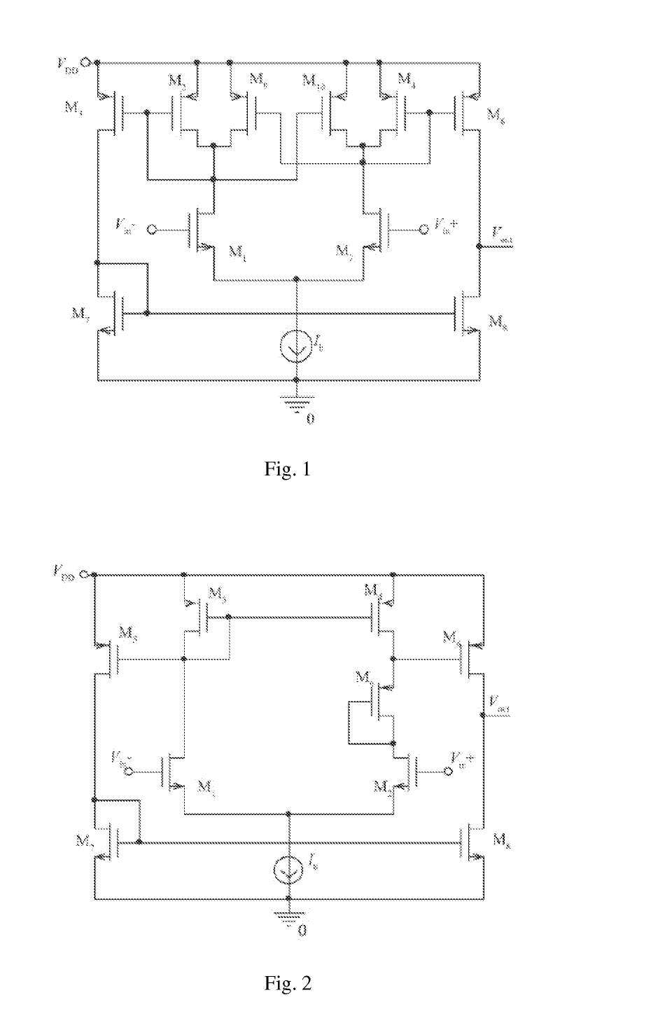

### DETAILED DESCRIPTION OF THE EMBODIMENTS

As in the description of the related art, the performance of the voltage comparator in CMOS image sensors is critical in enhancing the performance of the whole circuit. Hundreds and thousands of voltage comparators operating at the same time would help to lower the power consumption of the whole circuit, therefore benefit to limit the power consumption of the voltage comparator. The less the number of the transistors in the voltage comparator is, the smaller the area of both an entire pixel unit and the voltage comparator would be.

FIG. 2 is a topological structure chart of the voltage comparator in accordance with an exemplary embodiment of the present disclosure. The voltage comparator includes a current source I_{b}, a differential gain module, and a switch module. The magnitude of the current flowing through the current source I_{b} is nano ampere level.

The differential gain module is connected to the current source. The difference gain module includes a first transistor M1, a second transistor M2, a third transistor M3, a fourth transistor M4, and a ninth transistor M9. The first transistor M1 and the second transistor M2 are input differential pair transistors, the third transistor M3 and the fourth transistor M4 are active load transistors, and are electrically connected to active loads.

Both the source of the first transistor M1 and the source of the second transistor M2 are connected to a current source. The gate end of the second transistor M2 is connected to input voltage Vᵢₙ₊, the drain end of the second transistor M2 is connected to the source end and the drain end of the ninth transistor M9, the gate end of the first transistor M1 is input reference voltage Vᵢₙ₋, the drain end of the first transistor M1 is connected to the drain end of the third transistor M3.

The third transistor M3 and the fourth transistor M4 constructs to be a current mirror structure. The gate end of the third transistor M3 is connected to the gate end of the fourth transistor M4, the source end of the third transistor M3 is connected to the input work voltage V_{DD}, the drain end of the fourth transistor M4 is connected to the source end of the ninth transistor M9, the source end of the fourth transistor M4 is input work voltage VDD, the source end and the drain end of the ninth transistor M9 are connected.

The ninth transistor M9 is used to form asymmetric differential gain. The drain end and the gate end of the ninth transistor M9 are both connected to the drain end of the second transistor M2, the source end of the ninth transistor M9 is connected to the drain end of the fourth transistor M4, as a result, the differential gain module forms an asymmetric structure.

The switch module is used to switch between the differential gain module and the output terminal. The switch module includes a fifth transistor M5 connecting with the third transistor M3, a sixth transistor M6 connecting to the fourth transistor M4, a seventh transistor M7 connecting to the fifth transistor M5, an eighth transistor M8 connecting to the seventh transistor M7. Both the sixth transistor M6 and the eighth transistor M8 are connected to the output terminal.

Specifically, the gate end of the fifth transistor M5 is connected to the gate end and the drain end of the third transistor M3, the source end of the fifth transistor M5 is input work voltage V_{DD}.

The gate end of the sixth transistor M6 is connected to the drain end of the fourth transistor M4, the source end of the sixth transistor M6 is an input work voltage V_{DD}, the drain end of the sixth transistor M6 is connected to the output terminal.

The gate end of the seventh transistor M7 is connected to the gate end of the eighth transistor M8, the drain end of the seventh transistor M7 is connected to the fifth transistor M5, the source end of the seventh transistor M7 is grounded, and the gate end and the drain end of the seventh transistor M7 are connected.

The source end of the eighth transistor M8 is grounded, the drain end of the eighth transistor M8 is connected to the output terminal.

In an embodiment, the first transistor M1 and the second transistor M2 are NMOS, the third transistor M3 and the fourth transistor M4 are PMOS, the fifth transistor M5 and the sixth transistor M6 are PMOS, the seventh transistor M7 and the eighth transistor M8 are NMOS.

In order to increase the transconductance Gₘ of the input differential pair transistors, the first transistor M1 and the second transistor M2 work in the sub-threshold region. Comparing with working in saturation region, the transistors working in the sub-threshold region have bigger ratio of the transconductance and the current Gₘ/I_{b}, so that the power consumption is lower. The current and voltage in the input differential pair transistors are described as formula (3) and formula (4):

$$\frac{{I}_{D 1}}{{I}_{D 2}} = exp ( \frac{{V}_{ID}}{{nU}_{T}} ) \qquad ( 3 )$$

I_{D1}+I_{D2}=I_{b} (4)

wherein I_{D1}, I_{D2} are drain currents respectively flowing through the first transistor M1 and the second transistor M2, V_{ID} is the differential input voltage, I_{b} is the bias current.

The output current of the differential input stage is defined to be the current difference between currents flowing through active load transistors, that is, the output current of the first transistor M1 and the second transistor M2 is equal to the current difference between currents flowing through the third transistor M3 and the fourth transistor M4 respectively. Iₒᵤₜ=I_{D3}−I_{D4}.

$${I}_{OUT} = {I}_{b} tanh ( \frac{{V}_{ID}}{2 {nU}_{T}} ) \qquad ( 5 )$$

In order to reduce the input reference noise, the third transistor M3 and the fourth transistor M4 work in the strong inversion region.

The current of the voltage comparators of the present embodiment is provided by the bias current source I_{b}, the magnitude of the current I_{b} is nano ampere level, therefore, the input differential pair transistors is kept to work in the sub-threshold region.

The present disclosure provides voltage comparators with advantages of low power consumption and short latency time OTA used in CMOS image sensors with wide dynamic range, the voltage comparators also have fast respond speed.

In order to compare the performance of the voltage comparator provided by the current embodiments with that of the conventional partial positive feedback voltage comparator, the two Two kinds of voltage comparators are simulated with 0.6 μm DPDM standard digital CMOS process parameters, with the source voltage being 3.3V.

Referring to Table 1, sizes of each transistor according to the present embodiments are different, W and L respectively represents the channel width and channel length of the transistors. In order to simulate the latency time when the input voltage changes, the input signal Vin+ is set to be pulse voltage, the magnitude of the voltage is in the range from about 0 to about 2V, the rising/falling time is 250 ns, the pulse width is 5 μs, the period is 10 μs, the reference signal Vᵢₙ₋ is set to be 1.2V.

TABLE 1
the size of each transistor of the current embodiments

| Device | M₁ | M₂ | M₃ | M₄ | M₅ |
|---|---|---|---|---|---|
| W/μₘ | 20 | 20 | 1 | 3 | 2 |
| L/μₘ | 14 | 14 | 1 | 2 | 2 |
| Device | M₆ | M₇ | M₈ | M₉ | |
| W/μₘ | 2 | 2 | 2 | 2 | |
| L/μₘ | 2 | 14 | 14 | 5 | |

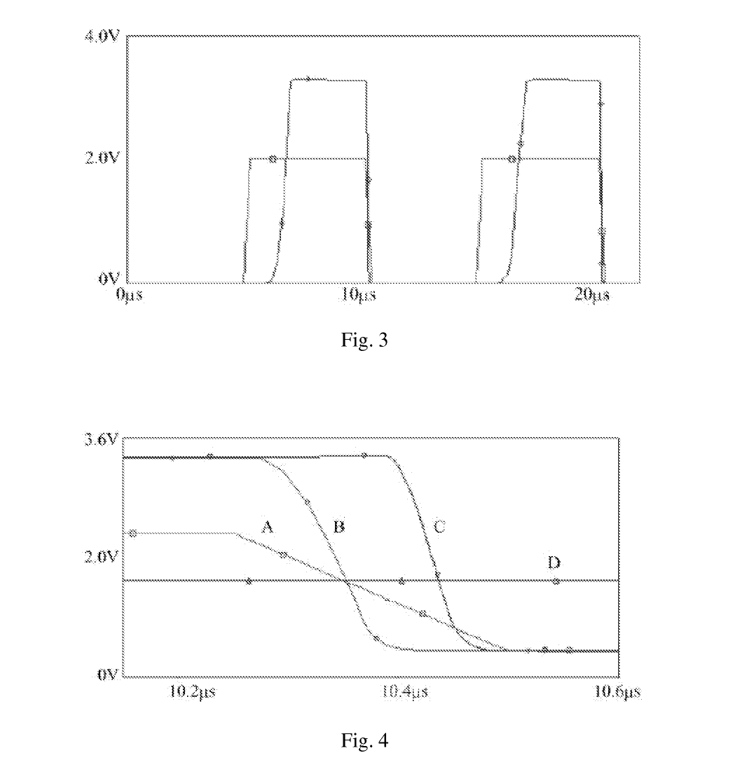

FIG. 3 is the output voltage transient response waveform of the voltage comparator of the embodiments. under the input condition that: the pulse voltage of input signal Vᵢₙ₊ changes in the range from about 0V to about 2V and the voltage of the power source is 0˜3.3V.

FIG. 4 shows the delay of waveform of the back edge of the output voltage relative to that of the input voltage respectively taken from the voltage comparator of the present embodiment and the conventional voltage comparator. Wherein the bias currents of the two voltage comparators are set to be I_{b}=1 μA, the curve A represents the back edge of the input voltage, the curve B represents the back edge of the output voltage taken from the waveform of the voltage comparator of the present embodiment, the curve C represents the back edge of the output voltage taken from the waveform of the conventional partial positive feedback voltage comparator, curve D represents the reference voltage.

Referring to FIG. 4, the latency time of the conventional partial positive feedback voltage comparator is 87 ns, the latency time of the voltage comparator of the present disclosure is 3 ns, which is far less than the latency time of the conventional partial positive feedback voltage comparator. By adjusting the voltage that provides the bias current Ib and the W/L ratio of the transistors, the bias current Ib can be adjusted. In order to satisfy the requirement of low power consumption (which is required to be no larger than 2 μW), the bias current of the voltage comparator of the present invention is set to be Ib=0.3 μA, the latency time of the voltage comparator is only 12 ns. When the rising/falling time is 1000 ns (with I_{b}=0.3 μA), the latency time of the conventional partial positive feedback voltage comparator is 216 ns, while the latency time of the voltage comparator of the present embodiment is 102 ns. When ideal pulse is input (with I_{b}=0.3 μA), the shortest latency time of the voltage comparator the present embodiment is 9 ns.

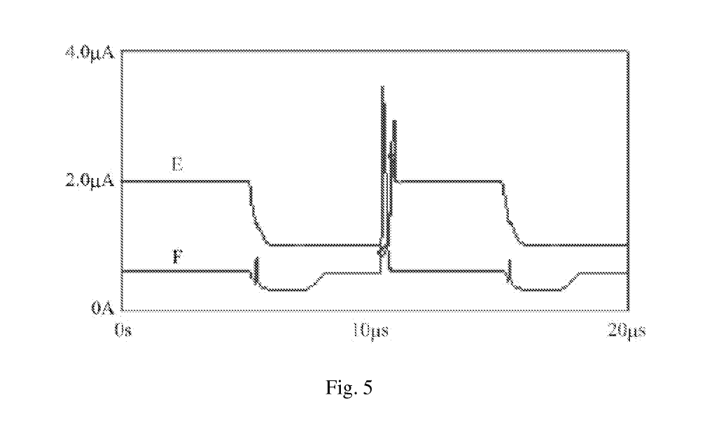

FIG. 5 shows the overall current waveforms in working state of the voltage comparator of the present embodiment and the conventional voltage comparator. Wherein the bias current I_{b} of the positive feedback voltage comparator and the voltage comparator of the present embodiment are respectively 1 μA and 0.3 μA. The curve E represents the overall working current of the positive feedback voltage comparator; the curve F represents the overall working current of the voltage comparator of the present embodiment.

Referring to FIG. 5, the maximum of the overall working current of the positive feedback voltage comparator is 2.016 μA, if the bias current of the positive feedback voltage comparator is decreased to 0.3 μA, the latency time will become very long and reach to about 193 ns. On the other hand, the overall working current of the voltage comparator of the present embodiment is no larger than 0.625 μA, thus the power consumption of the voltage comparator is about 2 μW when the power source is 3.3V.

Table 2 shows a comparison, under various bias currents, between the latency time and the power consumption respectively taken from the conventional voltage comparator and the voltage comparator of the present embodiment, given that the rising/falling time of the input pulse is 250 ns.

From the result of above simulation, the voltage comparator of the embodiments of the present disclosure is far better than the conventional positive feedback voltage comparator in the aspect of latency time and power consumption.

The voltage comparator of the present embodiment is based on standard OTA circuit and uses asymmetric topological structure. It has advantages of short latency time, low power consumption and simple structure, with the features that:
1) the asymmetric differential gain module is used in voltage comparators;
2) the input differential pair transistors (the first transistor M1 and the second transistor M2) is made to work in the sub-threshold region to increase the transconductance Gₘ of the input differential pair and finally lower power consumption.
3) the working region of the active load transistors (the third transistor M3 and the fourth transistor M4) is controlled to reduce input reference noise.

Although the present disclosure has been described with reference to the embodiments thereof and the best modes for carrying out the present disclosure, it is apparent to those skilled in the art that a variety of modifications and changes may be made without departing from the scope of the present disclosure, which is intended to be defined by the appended claims.

1. A voltage comparator comprising:
a current source;
a switch module; and
a differential gain module comprising a first transistor, a second transistor, a third transistor and a fourth transistor, wherein
the first transistor and the second transistor are respectively connected to the current source, the third transistor and the fourth transistor cooperatively form a mirror current structure, the third transistor is connected to the first transistor, and the fourth transistor is connected to the second transistor via a ninth transistor used for forming asymmetric differential gain.

2. The voltage comparator of claim 1, wherein the magnitude of current of the current source is nano ampere level.

3. The voltage comparator of claim 1, wherein a drain end and a gate end of the ninth transistor are both connected to a drain end of the second transistor, and a source end of the ninth transistor is connected to the drain end of the fourth transistor.

4. The voltage comparator of claim 1, wherein both the first transistor and second transistor work in the sub-threshold region.

5. The voltage comparator of claim 3, wherein the third transistor and fourth transistor work in the strong inversion region.

6. The voltage comparator of claim 1, wherein the switch module comprises:
a fifth transistor M5 connected to the third transistor M3;
a sixth transistor M6 connected to the fourth transistor M4;
a seventh transistor M7 connected to the fifth transistor M5; and
a eighth transistor M8 connected to the seventh transistor M7, wherein both the sixth transistor M6 and the eighth transistor M8 are connected to an output terminal.

7. The voltage comparator of claim 1, wherein output currents of the first transistor and the second transistor are both equal to the current difference between the current flowing through the third transistor and the fourth transistor respectively.

8. The voltage comparator of claim 1, wherein the first transistor and the second transistor are NMOS, and the third transistor and the fourth transistor are PMOS.

9. The voltage comparator of claim 1, wherein the fifth transistor and the sixth transistor are PMOS.

10. The voltage comparator of claim 1, wherein the seventh transistor and the eighth transistor are NMOS.

11. A voltage comparator comprising:
a current source;
an asymmetric differential gain module having a first transistor and a second transistor that works at the sub-threshold section;
a switch module for transferring an output signal of the asymmetric differential gain module to an output module.

12. The voltage comparator of claim 11, wherein the asymmetric differential gain module comprises:
a first transistor connecting to a third transistor;
a second transistor connecting to a fourth transistor through a ninth transistor;
wherein the third transistor and the fourth transistor cooperatively form a mirror current structure.

13. The voltage comparator of claim 4, wherein the third transistor and fourth transistor work in the strong inversion region.
